(19) United States
(12) Patent Application Publication
(10) Pub. No.: US 2008/0292445 A1
(43) Pub. Date: Nov. 27, 2008

(54) WAFER CARRIER AND BUFFER SUPPORT MEMBER THEREOF

(75) Inventor: Hiromi KURODA, Kumamoto-shi (JP)

Correspondence Address: YOUNG & THOMPSON, 209 Madison Street, Suite 500, ALEXANDRIA, VA, 22314, US

(73) Assignee: NEC ELECTRONICS CORPORATION, KAWASAKI (JP)

(21) Appl. No.: 12/124,318

(22) Filed: May 21, 2008

(30) Foreign Application Priority Data
May 25, 2007 (JP) 2007-138905

(51) Int. Cl. H01L 21/67

(52) U.S. Cl. 414/744.1

(57) ABSTRACT

A wafer carrier is to be provided which is capable of supporting semiconductor wafers with an appropriate load weight irrespective of the number loaded therein, and preventing the semiconductor wafers from being damaged due to an impact during transportation. An inner elastic mechanism that elastically supports an inner support member applies a greater load weight to front and back end portions of the inner support member, than to a central portion thereof. Accordingly, in the case where the wafer carrier is fully loaded with the semiconductor wafers, all the wafers are supported with a uniform and appropriate load weight. On the other hand, in the case where a fewer number of semiconductor wafers are to be loaded, for example placing the semiconductor wafers in a central region, where a smaller load weight is applied by the inner elastic mechanism to the inner support member, enables applying a uniform and appropriate load weight to all of the fewer number of semiconductor wafers.

This application is based on Japanese patent application No. 2007-138905, the content of which is incorporated hereinto by reference.

### BACKGROUND

1. Technical Field

The present invention relates to a wafer carrier that accommodates a plurality of semiconductor wafers coaxially aligned, and each orthogonally oriented with respect to the back and force direction, and to a buffer support member of such wafer carrier.

2. Related Art

Generally, a manufacturing process of a semiconductor device includes what is known as a wafer process, in which circuit patterns are formed on silicon wafers, covered with a protection layer, and subjected to electrical inspection. This is followed by a so-called assembly process, including assembling the wafers into desired packages and final inspection of the packages for delivery.

The wafer process and the assembly process are often executed in geographically distant plants, located in different prefectures of a country, or even in different countries. The wafers which have undergone a predetermined process in the plant that executes the wafer process are put in exclusive containers by lot, and transported to the plant for the assembly process, by truck or airfreight.

The wafer process plant of the semiconductor wafer purchases silicon wafers with no patterns formed thereon from a wafer manufacturer, in which case the silicon wafers are accommodated in exclusive wafer carriers, for delivery to the plant.

The wafer process plant does not scrap the wafer carriers, but reuses them when transporting the wafers between the wafer process plant and the assembly process plant, because this is more economical than newly producing the wafer carriers.

A conventional wafer carrier includes, for example, a groove formed inside a storage space for receiving a wafer sheet, a cover that closes the storage space from above, and a buffer material (cushion) provided on the inner side of the cover so as to retain the wafer. The wafer carrier is designed such that, upon fixing the storage space and the cover via an engaging portion, the wafer is fixed between the buffer material and the groove.

Such wafer carriers can be found, for example, in the following documents.

[Patented document 1] JP-U No. 2586364

[Patented document 2] JP-A No. H09-270459

[Patented document 3] JP-A No. 2005-294386

With the ongoing progress of reduction in thickness of the semiconductor packages, the wafer thickness after the wafer process is nowadays as thin as 300 μm, for example. The thickness of the silicon wafer purchased from the wafer manufacturer, which has not been subjected to any patterning, is 675 μm for example.

The difference of 375 μm corresponds to the portion of the back face of the wafer mechanically ground off by a grinder, after forming the cover layer in the wafer process. In other words, the thickness of the wafer is reduced to less than a half of the initial thickness, through the wafer process.

The foregoing wafer carrier is considered to have been designed on the assumption that the silicon wafer with no pattern formed thereon, i.e. having a thickness of 675 μm for example, is to be accommodated.

Accordingly, in the case of accommodating the wafer that has undergone the wafer process, i.e. the wafer of 300 μm in thickness for example, which is less than a half of the initial thickness, in the wafer carrier for transportation to the assembly process plant, a sudden impact may impose an excessive force to a portion of the wafer in contact with the buffer material or the groove, thereby cracking or breaking the wafer, which leads to lowered yield and productivity, and degraded customer satisfaction.

Upon accommodating the wafer in the wafer carrier and closing the cover, naturally a load weight is applied to the wafer between the groove that receives the wafer and the buffer material. Actual measurement of the load weight with a push-pull gauge with respect to a wafer carrier of a certain manufacturer (wafer diameter is 6 inches) has provided a value of approx. 6.6 kgs when 25 sheets of wafers are loaded (full), and approx. 5.5 kgs when 2 sheets of wafers are loaded.

A load weight imposed by a sudden impact during the transportation of the wafer carrier is added to the load weight initially applied to the wafer. It is experimentally known that the wafer of 675 μm in thickness can be exempted from cracking or breaking by the impact during the transportation.

However, the thinner wafer after being subjected to the wafer process, for example 300 μm in thickness, is smaller in cross-sectional area, and hence suffers a greater stress per area than does the wafer of 675 μm in thickness. The thinner wafer may, therefore, suffer a crack or breakdown owing to an excessive impact.

### SUMMARY

In one embodiment, there is provided a wafer carrier that accommodates a plurality of semiconductor wafers coaxially aligned with the wafer surface orthogonally oriented with respect to a forward-backward direction, comprising a lower periphery support member including a plurality of recessed grooves continuously aligned in a forward-backward direction, so as to be respectively engaged with an outer peripheral portion of a lower half of each of the plurality of semiconductor wafers; a pair of left and right outer support members of a slender shape extending in a forward-backward direction, and including a plurality of recessed grooves continuously aligned in a forward-backward direction to be respectively engaged with an outer peripheral portion of each semiconductor wafer; a pair of left and right inner support members of a slender shape extending in a forward-backward direction, and including a plurality of recessed grooves continuously aligned in a forward-backward direction to be respectively engaged with an outer peripheral portion of each semiconductor wafer; an outer elastic mechanism that elastically supports each of the pair of left and right outer support members, so as to cause the outer support members to be pressed against the upper peripheral portion of the semiconductor wafer from left and right sides; and an inner elastic mechanism that elastically supports each of the pair of left and right inner support members at an inner position than the pair of left and right outer support members, so as to cause the inner support members to be pressed against the upper peripheral portion of the semiconductor wafer from above; wherein the inner elastic mechanism applies a greater load weight causing the inner support members to be pressed against the semiconductor wafer, to a front and back end portions of the inner support members, than at least to another portion than the end portions.

In the wafer carrier thus constructed, the upper half of the semiconductor wafer having the lower half supported by the lower periphery support member is elastically supported by the pair of left and right outer support members from the left and right sides, and also elastically supported by the pair of left and right inner support members from above. The inner elastic mechanism thus elastically supporting the inner support member applies a greater load weight to the front and back end portions of the inner support members, than to a central region thereof. Accordingly, for example in the case where the wafer carrier is fully loaded with the semiconductor wafers, the inner support members are pressed against all the semiconductor wafers at a uniform and appropriate load weight. On the other hand, in the case where a fewer number of semiconductor wafers are to be loaded, for example placing the fewer number of semiconductor wafers in a central region, where a smaller load weight is applied by the inner elastic mechanism to the inner support member, enables applying a uniform and appropriate load weight to all of the fewer number of semiconductor wafers through the inner support members.

In another embodiment, there is provided a buffer support member for a wafer carrier that accommodates a plurality of semiconductor wafers coaxially aligned with the wafer surface orthogonally oriented with respect to a forward-backward direction, comprising a pair of left and right outer support members of a slender shape extending in a forward-backward direction, and including a plurality of recessed grooves continuously aligned in a forward-backward direction to be respectively engaged with an outer peripheral portion of each semiconductor wafer; a pair of left and right inner support members of a slender shape extending in a forward-backward direction, and including a plurality of recessed grooves continuously aligned in a forward-backward direction to be respectively engaged with an outer peripheral portion of each semiconductor wafer; an outer elastic mechanism that elastically supports each of the pair of left and right outer support members, so as to cause the outer support members to be pressed against the upper peripheral portion of the semiconductor wafer from left and right sides; and an inner elastic mechanism that elastically supports each of the pair of left and right inner support members at an inner position than the pair of left and right outer support members, so as to cause the inner support members to be pressed against the upper peripheral portion of the semiconductor wafer from above; wherein the inner elastic mechanism includes a plurality of elastically supporting beams that elastically supports the inner support member; and a relationship of A>B>C is satisfied, where A represents the number of elastically supporting beams located at the respective end portions of the inner elastic mechanism, B the number of elastically supporting beams located at a central portion of the inner elastic mechanism, and C the number of the elastically supporting beams located at an intermediate portion of the inner elastic mechanism, between the end portions and the central portion thereof.

It is to be noted that the constituents of the present invention do not necessarily have to be individually independent, but a plurality of constituents may be constituted as a single member; a constituent may be composed of a plurality of members; a constituent may be a part of another constituent; a part of a constituent and a part of another constituent may overlap; and so forth.

Also, the present invention specifies forward-backward, left and right, and upward and downward directions. It is to be noted, however, that such expression of directions is only for the explicitness of the description of the relative positions of the constituents of the present invention, and not intended for limiting the direction in the actual manufacturing process and use.

In the foregoing wafer carrier, the load weight applied by the inner elastic mechanism to the front and back end portions of the inner support members is greater than that applied to the central region thereof. Accordingly, for example in the case where the wafer carrier is fully loaded with the semiconductor wafers, the inner support members are pressed against all the semiconductor wafers at a uniform and appropriate load weight. On the other hand, in the case where a fewer number of semiconductor wafers are to be loaded, for example placing the fewer number of semiconductor wafers in a central region, where a smaller load weight is applied by the inner elastic mechanism to the inner support member, enables applying a uniform and appropriate load weight to all of the fewer number of semiconductor wafers through the inner support members. Thus, the wafer carrier according to the present invention is capable of supporting semiconductor wafers with an appropriate load weight irrespective of the number loaded therein, and thereby preventing the semiconductor wafers from being cracked or broken due to an impact or the like during the transportation.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are a schematic plan view and a front view respectively, showing a buffer support member of a wafer carrier according to an embodiment of the present invention;

FIG. 2 is a perspective view showing a structure of the buffer support member;

FIG. 3 is a schematic vertical cross-sectional view showing a state where semiconductor wafers are loaded in the wafer carrier;

FIG. 4 is another schematic vertical cross-sectional view showing a state where semiconductor wafers are loaded in the wafer carrier;

FIG. 5 is a schematic front view showing a state where a buffer support member supports the semiconductor wafer; and

FIG. 6 is a characteristic chart showing load weight distribution of various wafer carriers loaded with semiconductor wafers.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereunder, an exemplary embodiment of the present invention will be described in details, referring to the accompanying drawings. The following embodiment specifies forward-backward, left and right, and upward and downward directions. However, such expression of directions is only for the explicitness of the description of the relative positions of the constituents, and not intended for limiting the direction in the actual manufacturing process and use.

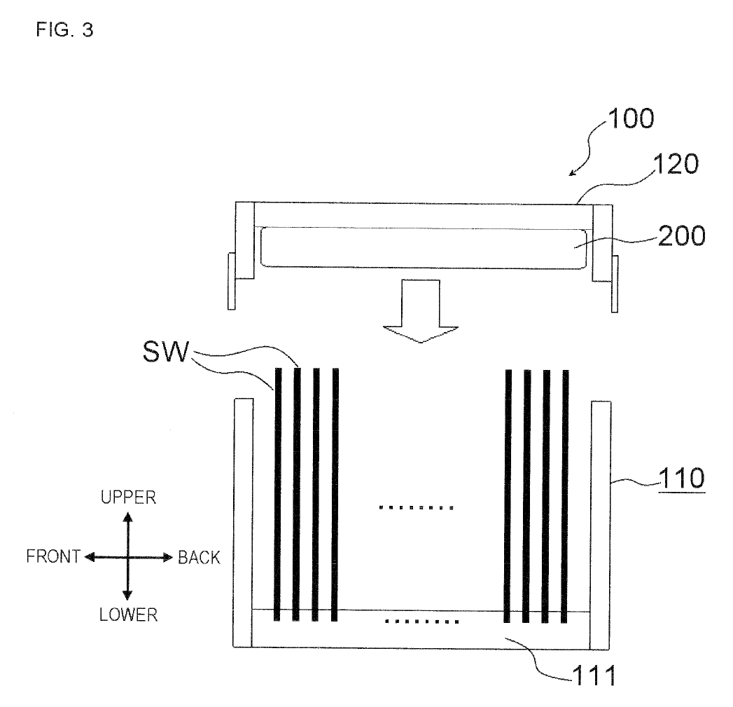

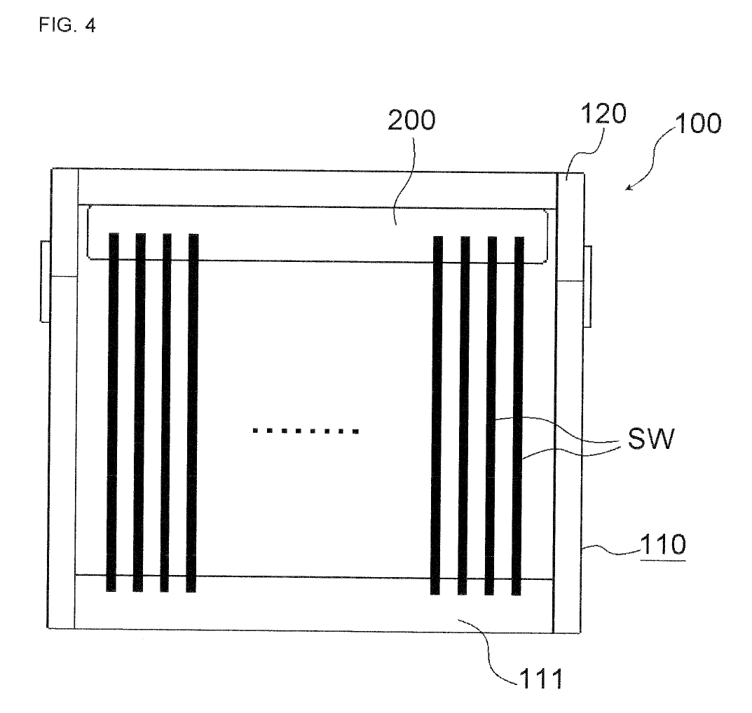

A wafer carrier 100 according to this embodiment accommodates a plurality of semiconductor wafers SW, coaxially aligned with the wafer surface orthogonally oriented with respect to a forward-backward direction. Accordingly, the wafer carrier 100 includes a carrier body 110 having an opening toward an upper direction through which the semiconductor wafers SW are inserted from above, and a carrier cover 120 that opens and closes the opening of the carrier body 110 from above, as shown in FIGS. 3 and 4.

The carrier body 110 includes a lower periphery support member 111 integrally formed at an inner lower portion thereof, on which a plurality of recessed grooves is continuously provided in a forward-backward direction so as to be respectively engaged with an outer peripheral portion of a lower half of each of the plurality of semiconductor wafers SW. To the lower surface of the carrier cover 120, a buffer support member 200 is attached.

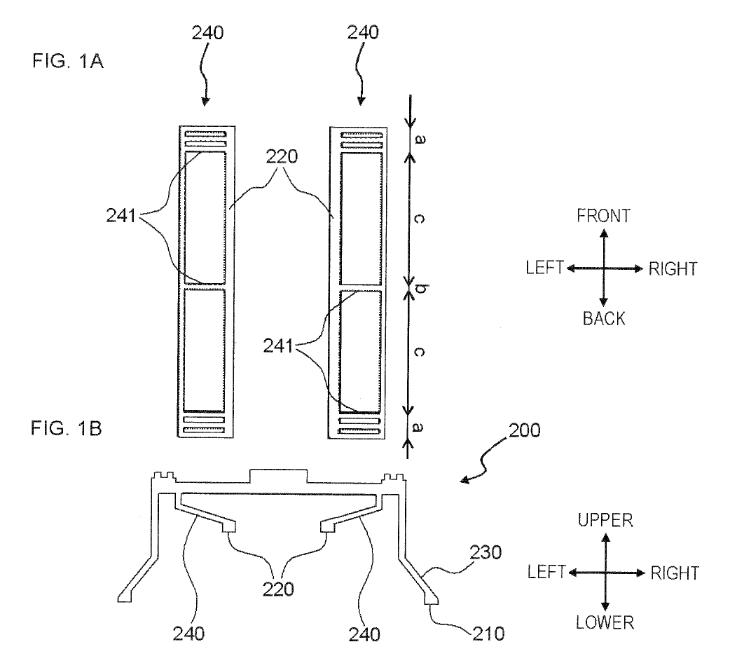

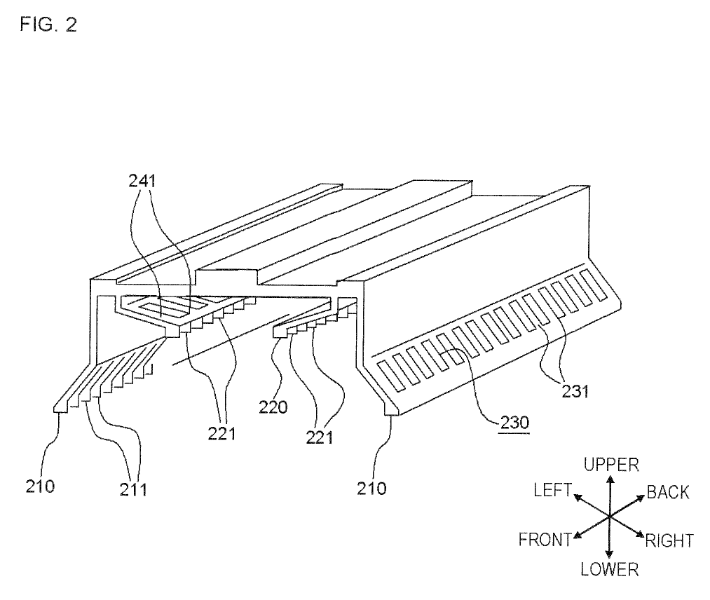

The buffer support member 200 includes, as shown in FIGS. 1A, 1B and 2, a pair of left and right outer support members 210 of a slender shape extending in a forward-backward direction, and including a plurality of recessed grooves 211 continuously aligned in a forward-backward direction to be respectively engaged with an outer peripheral portion of each semiconductor wafer SW, a pair of left and right inner support members 220 of a slender shape extending in a forward-backward direction, and including a plurality of recessed grooves 221 continuously aligned in a forward-backward direction to be respectively engaged with an outer peripheral portion of each semiconductor wafer SW, an outer elastic mechanism 230 that elastically supports each of the pair of left and right outer support members 210, so as to cause the outer support members 210 to be pressed against the upper peripheral portion of the semiconductor wafer SW from left and right sides, and an inner elastic mechanism 240 that elastically supports each of the pair of left and right inner support members 220 at an inner position than the pair of left and right outer support members 210, so as to cause the inner support members 220 to be pressed against the upper peripheral portion of the semiconductor wafer SW from above. Here, the inner elastic mechanism 240 applies a greater load weight causing the inner support members 220 to be pressed against the semiconductor wafer SW, to a front and back end portions of the inner support members 220, than at least to another portion than the end portions.

To be more detailed, the buffer support member 200 is, for example, a molded component of an elastic resin. Accordingly, the outer support member 210, the inner support member 220, the outer elastic mechanism 230, and the inner elastic mechanism 240 are integrally formed.

The inner elastic mechanism 240 includes a plurality of elastically supporting beams 241 that elastically supports the inner support member 220, such that a relationship of A>B>C is satisfied, where A represents the number of elastically supporting beams 241 located at the respective end portions of the inner elastic mechanism 240, B the number of the elastically supporting beams 241 located at a central portion of the inner elastic mechanism 240, and C the number of the elastically supporting beams 241 located at an intermediate portion of the inner elastic mechanism 240 between the end portions and the central portion thereof.

In the wafer carrier 100 according to this embodiment, the foregoing numbers are:

A=3

B=1

C=0

Further, the inner elastic mechanism 240 is formed such that a relationship of c>a>b is satisfied, where “a” represents the width of the front and back end portions where A pieces of elastically supporting beams 241 are respectively provided, “b” the width of the central portion in a forward-backward direction where B pieces of elastically supporting beams 241 are provided, and “c” the width of the intermediate portion in a forward-backward direction where no elastically supporting beam 241 is provided.

Accordingly, the inner elastic mechanism 240 satisfies a relationship of α>β>γ, where α represents the load weight causing the inner support member 220 to be pressed against the semiconductor wafer SW at the front and back end portions, β the load weight at the central portion, and γ the load weight at the intermediate portion, between the end portions and the central portion.

The outer elastic mechanism 230 also includes a plurality of elastically supporting beams 231 elastically supporting the outer support member 210. However, in the outer elastic mechanism 230, the plurality of elastically supporting beams 231 are evenly aligned from the front end portion to the back end portion.

Also, in the wafer carrier 100 according to this embodiment, in the case where, for example, semiconductor wafers SW including an orientation flat OF are to be loaded, the semiconductor wafers SW may be loaded so as to locate the orientation flat OF at the top, so that the inner support member 220 is pressed against the orientation flat OF by the inner elastic mechanism 240.

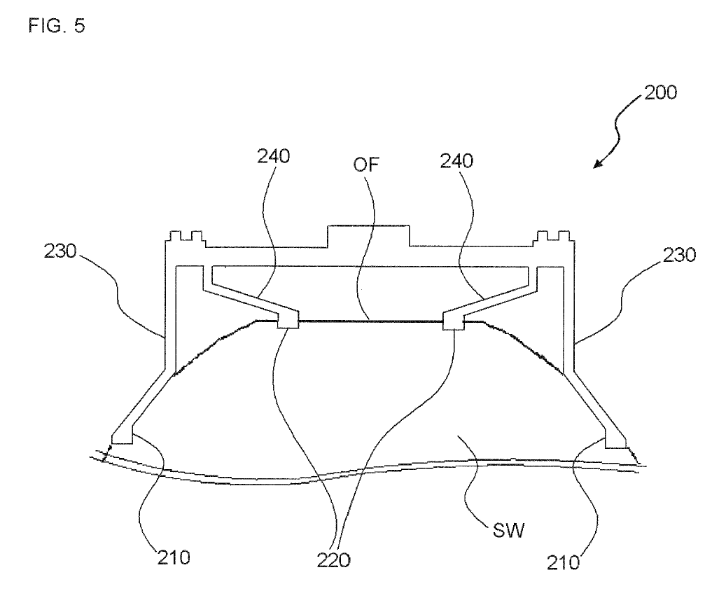

With the foregoing structure, in the wafer carrier 100 according to this embodiment, the upper half of the semiconductor wafer SW having the lower half supported by the lower periphery support member 111 is elastically supported by the pair of left and right outer support members 210 from the left and right sides, and also elastically supported by the pair of left and right inner support members 220 from above, as shown in FIGS. 3 to 5.

The inner elastic mechanism 240 thus elastically supporting the inner support member 220 includes, as already stated, three elastically supporting beams 241 at the respective end portions, and an elastically supporting beam 241 provided at the central portion.

Further, since the width “a” of the front and back end portions and the width “b” of the central portion where the elastically supporting beams 241 are provided, and the width “c” of the intermediate portion where no elastically supporting beam 241 is provided satisfy the relationship of c>a>b, the relationship of α>β>γ is satisfied among the load weight α causing the inner support member 220 to be pressed against the semiconductor wafer SW at the front and back end portions, the load weight β at the central portion, and the load weight γ at the intermediate portion, between the end portions and the central portion.

Therefore, in the wafer carrier 100 according to this embodiment, in the case where the wafer carrier 100 is fully loaded with the semiconductor wafers SW as shown in FIG. 3, the inner support members 220 are pressed against all of the semiconductor wafers SW at a uniform and appropriate load weight.

On the other hand, in the case where a fewer number of semiconductor wafers SW are to be loaded, for example placing the fewer number of semiconductor wafers SW in a central region, where a smaller load weight is applied by the inner elastic mechanism 240 to the inner support member 220, enables applying a uniform and appropriate load weight to all of the fewer number of semiconductor wafers SW through the inner support members 220.

Thus, the wafer carrier 100 according to this embodiment is capable of supporting semiconductor wafers SW with an appropriate load weight irrespective of the number loaded therein, and thereby preventing the semiconductor wafers SW from being cracked or broken due to an impact or the like during the transportation.

The present inventor actually made up the wafer carrier 100 of the foregoing structure, a wafer carrier (not shown) according to the conventional art in which the elastically supporting beams 241 are provided at regular intervals from the front end portion to the back end portion of the inner support member 220, and an experimental specimen of a wafer carrier (not shown) in which only one each of the elastically supporting beams 241 is provided at the front and back end portion of the inner support member 220.

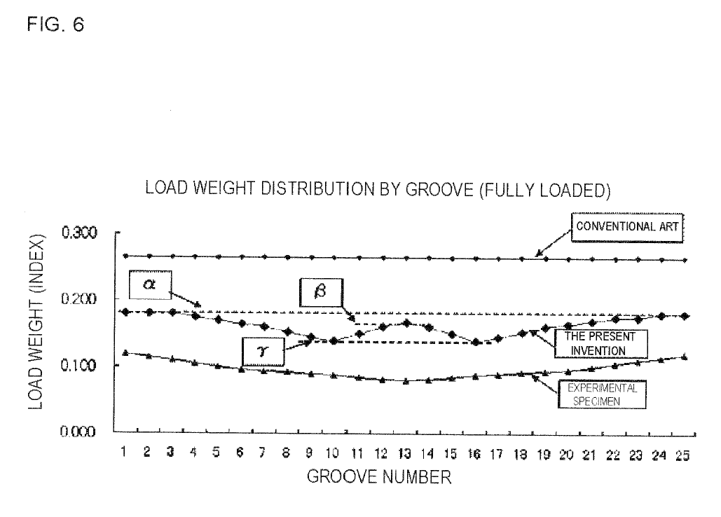

Each of the three types of wafer carriers 100 was fully loaded with the semiconductor wafers SW, and the load weight applied by the inner elastic mechanism 241 was measured. As a result, the three wafer carriers 100 respectively exhibited a different load weight distribution as shown in FIG. 6.

With the conventional wafer carrier in which the elastically supporting beams 241 are provided at regular intervals from the front end portion to the back end portion of the inner support member 220, it has been confirmed that the fully loaded semiconductor wafers SW can be elastically supported in a satisfactory condition.

In the case where a fewer number of semiconductor wafers SW are loaded, however, an excessive load weight is applied by the inner support member 220, via the multitude of elastically supporting beams 241. It has been confirmed that for such reason the semiconductor wafers SW are readily damaged by an impact or vibration during the transportation. It has also been confirmed that such excessive load weight cannot be alleviated no matter at which position of the wafer carrier the fewer number of semiconductor wafers SW may be placed.

On the other hand, with the experimental specimen in which only one each of the elastically supporting beams 241 is provided at the front and back end portions of the inner support member 220, the semiconductor wafers SW were elastically supported in a good condition provided that the number of semiconductor wafers SW was fewer.

In the case where a larger number of semiconductor wafers SW are loaded, however, the load weight becomes insufficient. It has been confirmed that, for such reason, the semiconductor wafers SW fall off from the inner support member 220, owing to an impact or vibration during the transportation.

With the wafer carrier 100 according to this embodiment, it has been confirmed that the load weight acting on thin semiconductor wafers SW subjected to grinding of the back surface (diameter 6 inches, thickness approx. 300 μm to 350 μm) can be adjusted to be smaller than “approx. 6.6 kgs when fully loaded with 25 wafers, and approx. 5.5 kgs when loaded with 2 wafers” at maximum, and greater than at least “approx. 2.6 kgs when fully loaded with 25 wafers, and approx. 2.1 kgs when loaded with 2 wafers”.

Further, it has been confirmed that the load weight acting on the semiconductor wafer SW can be adjusted to be “approx. 4.0 kgs when fully loaded with 25 wafers, and approx. 3.4 kgs when loaded with 2 wafers”. The fully loaded semiconductor wafers SW could be elastically supported in a satisfactory condition.

Moreover, it has been confirmed that, in the case where a fewer number of semiconductor wafers SW are to be loaded, placing the semiconductor wafers SW in a position where a smaller load weight is applied enables elastically supporting the semiconductor wafers SW with an appropriate load weight, despite the number thereof is fewer.

In particular, the foregoing wafer carrier 100 includes an elastically supporting beam 241 at the central portion of the inner support member 220. It has been confirmed that such structure prevents an extreme lack of load weight at the central region, thereby facilitating elastically supporting even a single semiconductor wafer SW properly.

A single piece of semiconductor wafer SW was placed in the wafer carrier and the wafer carrier was packed for actual transportation, for executing a destructive inspection of dropping the package from a height assumed in the actual transportation, to see if the semiconductor wafer SW in the wafer carrier withstands the impact.

As a result, it has been confirmed that with the conventional wafer carrier the semiconductor wafer SW may be broken at the elevation of 50 cm or higher, while with the wafer carrier 100 according to the present invention the semiconductor wafer SW remains undamaged even when dropped from the height of 1 meter.

Further, the present inventor executed an experiment of actually loading the wafer carrier 100 containing the semiconductor wafers SW on a truck and transporting the wafer carrier 100 through a round trip over a distance of approx. 100 km one way. With such experiment also, it has been confirmed that the semiconductor wafers SW in the wafer carrier 100 can remain free from a damage.

The present invention is not limited to the foregoing embodiment, but allows various modifications within the scope of the present invention. Also, although the foregoing embodiment and variations specifically describe the structure of the constituents, the structure may be modified in so far as the function according to the present invention is satisfied.

It is apparent that the present invention is not limited to the above embodiment, and may be modified and changed without departing from the scope and spirit of the invention.

What is claimed is:

1. A wafer carrier that accommodates a plurality of semiconductor wafers coaxially aligned with a surface thereof orthogonally oriented with respect to a forward-backward direction, comprising:
a lower periphery support member including a plurality of recessed grooves continuously aligned in a forward-backward direction, so as to be respectively engaged with an outer peripheral portion of a lower half of each of said plurality of semiconductor wafers;
a pair of left and right outer support members of a slender shape extending in a forward-backward direction, and including a plurality of recessed grooves continuously aligned in a forward-backward direction to be respectively engaged with an outer peripheral portion of each semiconductor wafer;
a pair of left and right inner support members of a slender shape extending in a forward-backward direction, and including a plurality of recessed grooves continuously aligned in a forward-backward direction to be respectively engaged with an outer peripheral portion of each semiconductor wafer;
an outer elastic mechanism that elastically supports each of said pair of left and right outer support members, so as to cause said outer support members to be pressed against said upper peripheral portion of said semiconductor wafer from left and right sides; and
an inner elastic mechanism that elastically supports each of said pair of left and right inner support members at an inner position than said pair of left and right outer support members, so as to cause said inner support members to be pressed against said upper peripheral portion of said semiconductor wafer from above;
wherein said inner elastic mechanism applies a greater load weight causing said inner support members to be pressed against said semiconductor wafer, to a front and back end portions of said inner support members, than at least to another portion than said end portions.

2. The wafer carrier according to claim 1, wherein said inner elastic mechanism satisfies a relationship of:
α>β>γ,
where α represents a load weight causing said inner support member to be pressed against said semiconductor wafer at front and back end portions, β a load weight at a central portion, and γ a load weight at an intermediate portion between said end portions and said central portion.

3. The wafer carrier according to claim 1, wherein said inner elastic mechanism includes a plurality of elastically supporting beams that elastically supports said inner support member, and satisfies a relationship of:
A>B>C,
where A represents the number of elastically supporting beams located at the respective end portions of said inner elastic mechanism, B the number of said 10 elastically supporting beams located at a central portion of said inner elastic mechanism, and C the number of said elastically supporting beams located at said intermediate portion of said inner elastic mechanism, between said end portions and said central portion thereof.

4. The wafer carrier according to claim 3, wherein the number of said elastically supporting beams C located at said intermediate portion satisfies:
C=0.

5. The wafer carrier according to claim 2, wherein said inner elastic mechanism satisfies a relationship of:
c>a>b,
where “a” represents a width of said front and back 5 end portions in a forward-backward direction, “b” a width of said central portion in a forward-backward direction, and “c” a width of said intermediate portion in a forward-backward direction.

6. The wafer carrier according to claim 1, comprising a buffer support member including said pair of left and right outer support members, said pair of left and right inner support members, said outer elastic mechanism, and said inner elastic mechanism, formed into a unified body.

7. The wafer carrier according to claim 6, further comprising a carrier body having an opening toward an upper direction through which said semiconductor wafer is to be inserted from above, and
a carrier cover that opens and closes said opening of said carrier body from above;
wherein said carrier cover includes a buffer support member attached to a lower surface thereof.

8. A buffer support member of a wafer carrier that accommodates a plurality of semiconductor wafers coaxially aligned with a surface thereof orthogonally oriented with respect to a forward-backward direction, comprising:
a pair of left and right outer support members of a slender shape extending in a forward-backward direction, and including a plurality of recessed grooves continuously aligned in a forward-backward direction to be respectively engaged with an outer peripheral portion of each semiconductor wafer;
a pair of left and right inner support members of a slender shape extending in a forward-backward direction, and including a plurality of recessed grooves continuously aligned in a forward-backward direction to be respectively engaged with an outer peripheral portion of each semiconductor wafer;
an outer elastic mechanism that elastically supports each of said pair of left and right outer support members, so as to cause said outer support members to be pressed against said upper peripheral portion of said semiconductor wafer from left and right sides; and
an inner elastic mechanism that elastically supports each of said pair of left and right inner support members at an inner position than said pair of left and right outer support members, so as to cause said inner support members to be pressed against said upper peripheral portion of said semiconductor wafer from above;
wherein said inner elastic mechanism includes a plurality of elastically supporting beams that elastically supports said inner support member; and
a relationship of:
A>B>C
is satisfied, where A represents the number of elastically supporting beams located at the respective end portions of said inner elastic mechanism, B the number of said elastically supporting beams located at a central portion of said inner elastic mechanism, and C the number of said elastically supporting beams located at an intermediate portion of said inner elastic mechanism, between said end portions and said central portion thereof.
